(19) United States
(12) Patent Application Publication
(10) Pub. No.: US 2026/0262511 A1
(43) Pub. Date: Sep. 3, 2026

(54) PACKAGE COMPRISING A HEAT SINK

(71) Applicant: QUALCOMM Incorporated, San Diego, CA (US)

(72) Inventors: Aniket PATIL, San Diego, CA (US); Manuel ALDRETE, Encinitas, CA (US); Bohan YAN, San Diego, CA (US)

(21) Appl. No.: 19/067,618

(22) Filed: Feb. 28, 2025

(51) Int. Cl. H01L 23/538; H01L 23/31; H01L 23/373; H01L 23/498; H01L 25/00; H01L 25/18; H10D 1/68

(52) U.S. Cl. CPC H10W 70/611; H10W 40/258; H10W 90/00; H10W 90/401; H10D 1/714; H10D 1/716; H10W 74/111; H10W 90/701

(57) ABSTRACT

A package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; at least one passive device located between the second integrated device and the third integrated device; and at least one heat sink located between the second integrated device and the third integrated device.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages, including package with improved thermal performances. There is also an ongoing need to reduce the overall size of the packages.

### SUMMARY

Various features relate to packages with substrates and integrated devices.

One example provides a package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; at least one passive device located between the second integrated device and the third integrated device; and at least one heat sink located between the second integrated device and the third integrated device.

Another example provides a package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; and at least two heat sinks located between the second integrated device and the third integrated device.

A method for fabricating a package. The method provides a first substrate. The method couples a first integrated device to the first substrate. The method couples a second substrate to the first substrate through at least a plurality of solder interconnects. The method provides an encapsulation layer located between the first substrate and the second substrate. The method couples a second integrated device to the second substrate through a second plurality of solder interconnects. The method couples a third integrated device to the second substrate through a third plurality of solder interconnects. The method provides at least two heat sinks located between the second integrated device and the third integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, integrated devices, a heat sink and a passive device.

FIG. 2 illustrates an exemplary cross sectional plan view of a package that includes a substrate, integrated devices, a heat sink and a passive device.

FIG. 3 illustrates an exemplary cross sectional profile view of a passive device.

FIGS. 4A-4E illustrate an exemplary sequence for fabricating a package that includes a substrate, integrated devices, a heat sink and a passive device.

FIG. 5 illustrates an exemplary flow chart of a method for fabricating a package that includes a substrate, integrated devices, a heat sink and a passive device.

FIG. 6 illustrates an exemplary cross sectional plan view of a package that includes a substrate, integrated devices and heat sinks.

FIG. 7 illustrates an exemplary cross sectional plan view of a package that includes a substrate, integrated devices, heat sinks and passive devices.

FIGS. 8A-8C illustrate an exemplary sequence for fabricating a substrate.

FIG. 9 illustrates an exemplary flow chart of a method for fabricating a substrate.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; at least one passive device located between the second integrated device and the third integrated device; and at least one heat sink located between the second integrated device and the third integrated device.

### Exemplary Package Comprising a Heat Sink and a Passive Device

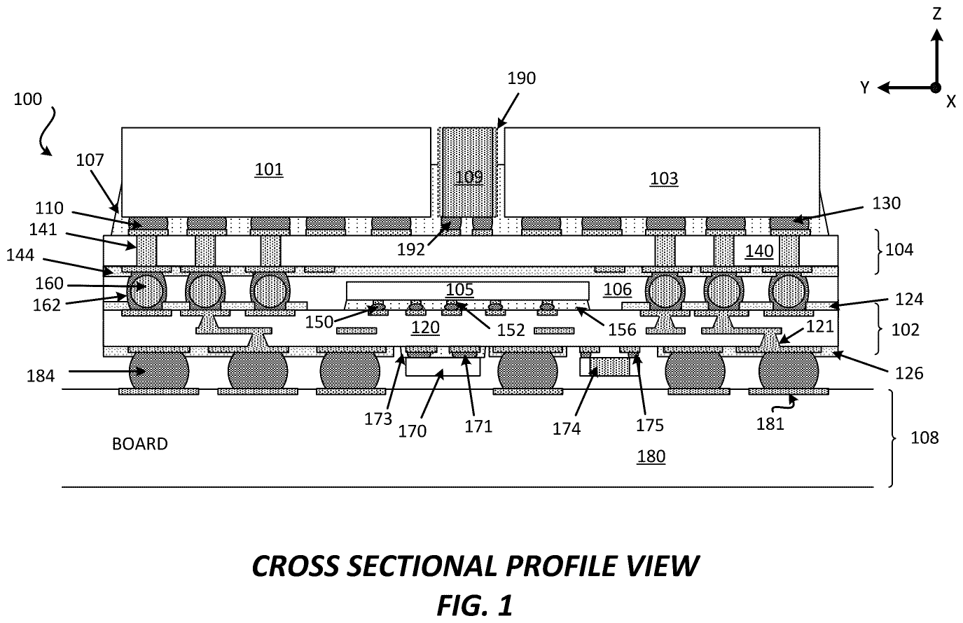

FIG. 1 illustrates a cross sectional profile view of a package 100 that may include integrated devices, at least one heat sink and at least one passive device. The package 100 may be a package on package (PoP). The package 100 may be coupled to a board 108 through a plurality of solder interconnects 184. The board 108 may include at least one board dielectric layer 180 and a plurality of board interconnects 181. The board 108 may include a printed circuit board (PCB).

The package 100 may include an integrated device 101, an integrated device 103, a heat sink 190, a passive device 109, a substrate 102, a substrate 104, an integrated device 105, an encapsulation layer 106, a plurality of core balls 160, a plurality of solder interconnects 162, a passive device 170, a passive device 174, an underfill 107, an underfill 156, and a plurality of solder interconnects 130.

The substrate 102 may include at least one dielectric layer 120, a plurality of interconnects 121, a solder resist layer 124 and a solder resist layer 126. The substrate 102 may be a coreless substrate. In some implementations, the at least one dielectric layer 120 may include prepreg and/or polyimide. However, different implementations may use different materials for the at least one dielectric layer 120. The substrate 102 may be coupled to the board 108 through the plurality of solder interconnects 184. The plurality of solder interconnects 184 may be coupled to the plurality of interconnects 121 and the plurality of board interconnects 181.

The substrate 104 may include at least one dielectric layer 140, a plurality of interconnects 141 and a solder resist layer 144. The substrate 104 may be an interposer. The plurality of interconnects 141 may be a plurality of interposer interconnects. In some implementations, the at least one dielectric layer 140 may include silicon (Si). However, different implementations may use different materials for the at least one dielectric layer 140. The substrate 104 may be coupled to the substrate 102 through the plurality of core balls 160 and/or the plurality of solder interconnects 162. The plurality of core balls 160 and/or the plurality of solder interconnects 162 may be coupled to and touch (i) the plurality of interconnects 121 of the substrate 102 and (ii) the plurality of interconnects 141 of the substrate 104. The plurality of core balls 160 may include a plurality of copper balls. The plurality of core balls 160 and/or the plurality of solder interconnects 162 may be located between the substrate 102 and the substrate 104. The plurality of core balls 160 may include a plurality of ball interconnects and/or core ball interconnects. The plurality of core balls 160 may include a plurality of copper balls. It is noted that one or more of the core balls from the plurality of core balls 160 do not need to be perfectly spherical in shape and/or form. In some implementations, the substrate 102 may be a first substrate and the substrate 104 may be a second substrate. In some implementations, the substrate 104 may be a first substrate and the substrate 102 may be a second substrate. In some implementations, the substrate 102 may be a different type of substrate from the substrate 104. In some implementations, the substrate 102 may be a similar type of substrate to the substrate 104. In some implementations, the substrate 102 may be a same type of substrate as the substrate 104.

The integrated device 105 may be coupled to a first surface (e.g., top surface) of the substrate 102. The integrated device 105 may be coupled to the substrate 102 through a plurality of pillar interconnects 152 and/or a plurality of solder interconnects 150. The plurality of solder interconnects 150 may be coupled to the plurality of interconnects 121 and the plurality of pillar interconnects 152. The underfill 156 may be located between the integrated device 105 and the substrate 102. The underfill 156 may at least partially encapsulate the plurality of pillar interconnects 152 and/or the plurality of solder interconnects 150. The integrated device 105 may be located between the substrate 102 and the substrate 104.

The encapsulation layer 106 is located between the substrate 102 and the substrate 104. The encapsulation layer 106 may include a mold, a resin, an epoxy and/or a filler. The encapsulation layer 106 may at least partially encapsulate the plurality of core balls 160, the plurality of solder interconnects 162, the integrated device 105 and/or the underfill 156. The encapsulation layer 106 may be provided by using a compression and transfer molding process, a sheet molding process, or a liquid molding process.

The passive device 170 may be coupled to a second surface (e.g., bottom surface) of the substrate 102. The passive device 170 may be coupled to the plurality of interconnects 121 of the substrate 102 through a plurality of solder interconnects 171. The passive device 170 may include a passive integrated device. An underfill 173 may be located between the passive device 170 and the substrate 102.

The passive device 174 may be coupled to a second surface (e.g., bottom surface) of the substrate 102. The passive device 174 may be coupled to the plurality of interconnects 121 of the substrate 102 through a plurality of solder interconnects 175. The passive device 174 may include a capacitor (e.g., surface mount capacitor).

The integrated device 101 is coupled to a first surface (e.g., top surface) of the substrate 104 through a plurality of solder interconnects 110. The plurality of solder interconnects 110 may be coupled to the integrated device 101 and the plurality of interconnects 141. The integrated device 103 is coupled to a first surface (e.g., top surface) of the substrate 104 through a plurality of solder interconnects 130. The plurality of solder interconnects 130 may be coupled to the integrated device 103 and the plurality of interconnects 141.

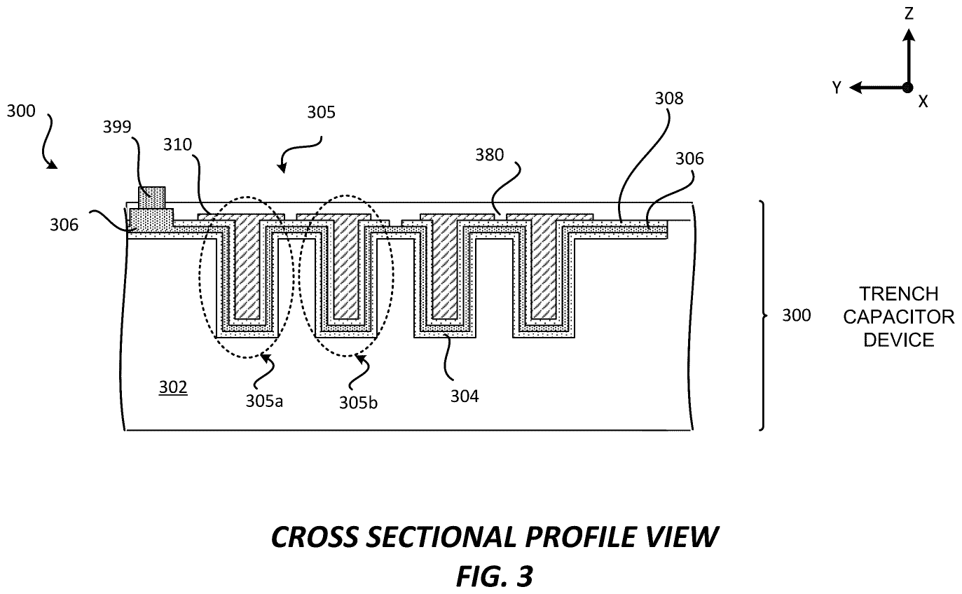

The passive device 109 is coupled to the first surface of the substrate 104 through a plurality of solder interconnects 192. The plurality of solder interconnects 192 may be coupled to the passive device 109 and the plurality of interconnects 141. The passive device 109 may include different types of passive devices. The passive device 109 may include a deep trench capacitor device. An example of a deep trench capacitor device is illustrated and described below in at least FIG. 3. The passive device 109 may be a passive integrated device. The passive device 109 may be a discrete capacitor. The passive device 109 may be located laterally between the integrated device 101 and the integrated device 103. The passive device 109 may vertically overlap with the integrated device 105. The passive device 109 may be configured to be electrically coupled to power (e.g., power distribution network). The passive device 109 may include a passive integrated device. The passive device 109 may include a discrete passive device.

The heat sink 190 is coupled to the first surface of the substrate 104 through at least one solder interconnect (not shown). The at least one solder interconnect may be coupled to the heat sink 190 and the plurality of interconnects 141. The heat sink 190 may include a material with a high thermal conductivity. The heat sink 190 may include copper and/or aluminum. The heat sink 190 may be located laterally between the integrated device 101 and the integrated device 103. The heat sink 190 may vertically overlap with the integrated device 105. The heat sink 190 may be laterally adjacent to the passive device 109. In some implementations, the heat sink 190 and/or the passive device 109 may be located in a lateral gap and/or a lateral space between the integrated device 101 and the integrated device 103. The underfill 107 may be located between the integrated device 101 and the substrate 104. The underfill 107 may be located between the integrated device 103 and the substrate 104. The underfill 107 may be located between the heat sink 190 and the substrate 104. The underfill 107 may be located between the passive device 109 and the substrate 104. The underfill 107 may be located between the integrated device 101 and the integrated device 103.

In some implementations, there may be one or more heat sinks and/or one or more passive devices in the lateral space and/or the lateral gap between the integrated device 101 and the integrated device 103. The use and/or location of the heat sink (e.g., 190) helps dissipate heat effectively and efficiently from the integrated device 105 and the use and/or location of the passive device (e.g., 109) provides efficient use of the space in the package, which can help provide a package with a compact form factor. In some implementations, the use of multiple smaller heat sinks instead of a long single heat sink may help improve heat dissipation by at least 3 percent. In addition, providing smaller heat sink instead of one large heat sink, provides a package with a more reliable coupling between the heat sinks and the substrate 104. This may be because large heat sinks and/or larger heat sinks are difficult to handle and properly place in a package than smaller heat sinks.

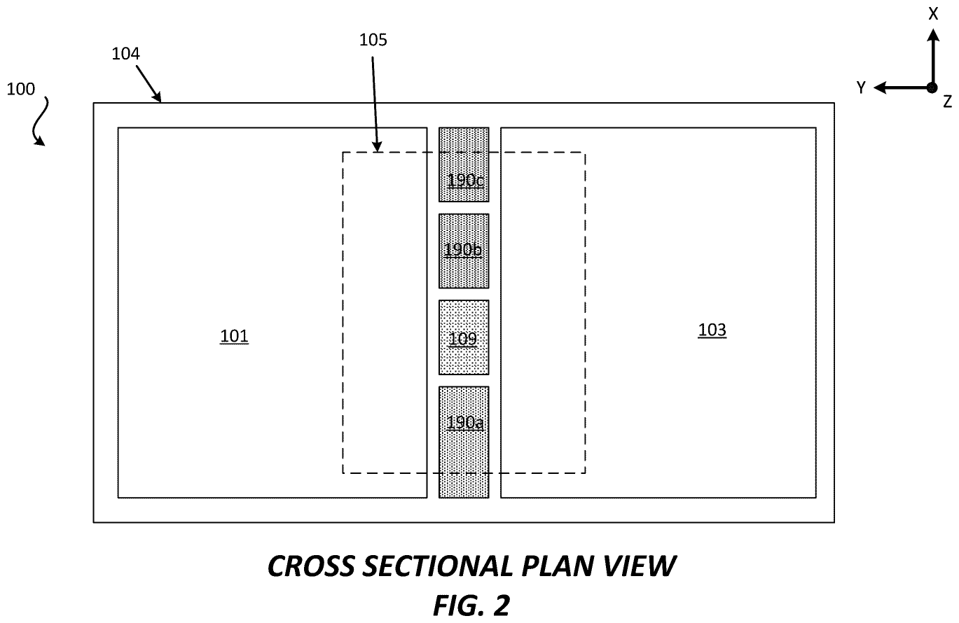

FIG. 2 illustrates a cross section plan view of the package 100. The package 100 may include the substrate 104, the integrated device 105, the integrated device 101, the integrated device 103, the passive device 109, the heat sink 190a, the heat sink 190b and the heat sink 190c. The passive device 109, the heat sink 190a, the heat sink 190b and the heat sink 190c are located laterally between the integrated device 101 and the integrated device 103. The passive device 109, the heat sink 190a, the heat sink 190b and the heat sink 190c are arranged in a row between the integrated device 101 and the integrated device 103. The passive device 109, the heat sink 190a, the heat sink 190b and/or the heat sink 190c vertically overlap with at least a portion of the integrated device 105. The passive device 109, the heat sink 190a, the heat sink 190b and the heat sink 190c are coupled to the substrate 104. The passive device 109, the heat sink 190a, the heat sink 190b and the heat sink 190c may be coupled to the substrate 104 through a plurality of solder interconnects. The passive device 109 is located laterally between the heat sink 190a and the heat sink 190b. Different implementations may have different numbers of the heat sinks (e.g., 190a) and/or different numbers of the passive devices (e.g., 109). Different implementations may have different configurations and/or arrangements of the heat sink and/or the passive device. Different implementations may have one or more heat sinks with different sizes and/or shapes. Different implementations may have one or more passive devices with different sizes and/or shapes. Different implementations may have one or more passive devices with different passive device types. In some implementations, using smaller heat sinks instead of one long heat sink provides a more reliable coupling between the heat sink and the substrate 104, which helps provide more effective and efficient heat dissipation away from the integrated device 105. In some implementations, a length of a heat sink (e.g., 190) and/or a length of a passive device (e.g., 109) may be less than 50 percent of (i) a length and/or a width of the integrated device 101 and/or (ii) a length and/or a width of the integrated device 103.

FIG. 3 illustrates a cross sectional profile view of a passive device 300 that is configured as a trench capacitor device. The passive device 300 may be an integrated passive device. The passive device 300 may represent any of the passive devices described in the disclosure. For example, the passive device 300 may represent the passive device 109. The passive device 300 may be an integrated passive device that includes multiple trench capacitors (e.g., deep trench capacitors). The passive device 300 may be a means for trench capacitance. The passive device 300 includes a front side and a back side. The front side of the passive device 300 may include the plurality of trench capacitors.

The passive device 300 includes a passive device substrate 302 and a plurality of trench capacitors 305. A plurality of solder interconnects (not shown) may be coupled to the passive device 300. The passive device substrate 302 may include silicon (Si). The passive device substrate 302 may include a plurality of trenches and/or cavities over which capacitors may be formed.

The plurality of trench capacitors 305 includes a trench capacitor 305a and a trench capacitor 305b. In some implementations, the trench capacitor 305a and the trench capacitor 305b may be configured to be part of a same capacitor (e.g., first capacitor, first trench capacitor). In some implementations, the trench capacitor 305a and the trench capacitor 305b may be configured to be coupled to and/or part of a first power distribution network (PDN). The trench capacitor 305a and the trench capacitor 305b may be configured to be part of a first electrical path for a first power for a package. The trench capacitor 305a and the trench capacitor 305b may be configured to be coupled to integrated device(s).

As shown in FIG. 3, the passive device 300 includes the passive device substrate 302, an oxide layer 304, a first electrically conductive layer 306, a dielectric layer 308, a second electrically conductive layer 310 and a dielectric layer 380. The first electrically conductive layer 306 and/or the second electrically conductive layer 310 may include polysilicon. The oxide layer 304 and/or the dielectric layer 308 may include SiO₂ (e.g., low-pressure chemical vapor deposition (LPCVD) SiO₂) or Si₃N₄ (e.g., LPCVD Si₃N₄). Portions of the oxide layer 304, the first electrically conductive layer 306, the dielectric layer 308, and the second electrically conductive layer 310 may be located in trenches and/or cavities of the passive device substrate 302. The dielectric layer 380 may include silicon nitride. It is noted that a passive device substrate 302 may be considered to have a trench or a cavity, even if the trench or the cavity is filled with one or more materials.

The trench capacitor 305a (e.g., first trench capacitor, first capacitor, means for first trench capacitance) may be defined by (i) a first portion of the oxide layer 304, (ii) a first portion of the first electrically conductive layer 306, (iii) a first portion of the dielectric layer 308, and (iv) a first portion of the second electrically conductive layer 310 that are located in a trench (e.g., first trench) of the passive device substrate 302.

The trench capacitor 305b (e.g., second trench capacitor, second capacitor, means for second trench capacitance) may be defined by (i) a second portion of the oxide layer 304, (ii) a second portion of the first electrically conductive layer 306, (iii) a second portion of the dielectric layer 308, and (iv) a second portion of the second electrically conductive layer 310 that are located in a trench (e.g., second trench) of the passive device substrate 302. It is noted that trench capacitor 305b may be part of a same capacitor as the trench capacitor 305a. That is, the trench capacitor 305a and the trench capacitor 305b may be configured to be electrically coupled together to form a capacitor (e.g., first capacitor) with a greater capacitance. The passive device 300 may also optionally include a post interconnect 399 that is coupled to the first electrically conductive layer 306. The passive device may also include other post interconnects that are coupled to other second electrically conductive layer 310. The post interconnect 399 may be part of a plurality of post interconnects.

An integrated device (e.g., 101, 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . .). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package Comprising a Heat Sink and a Passive Device

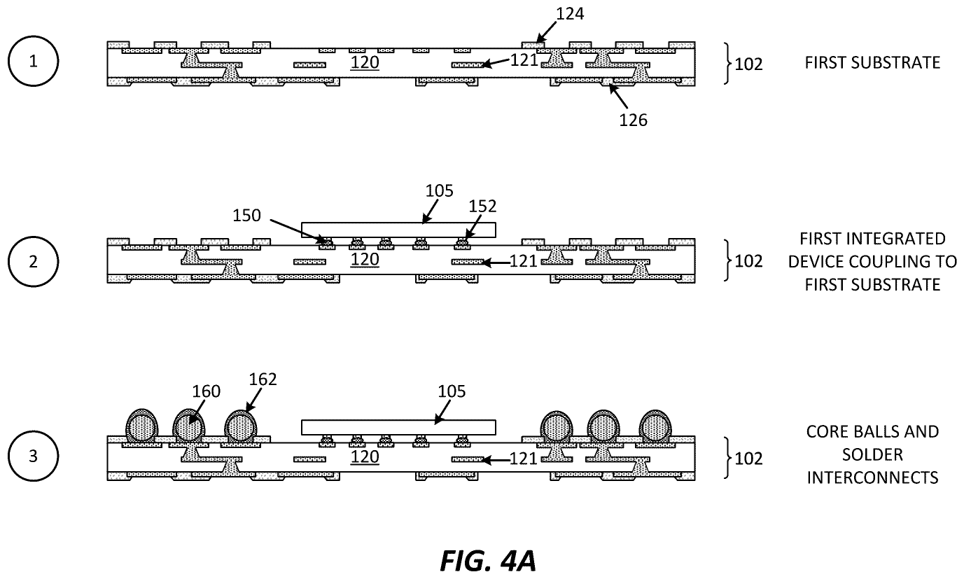

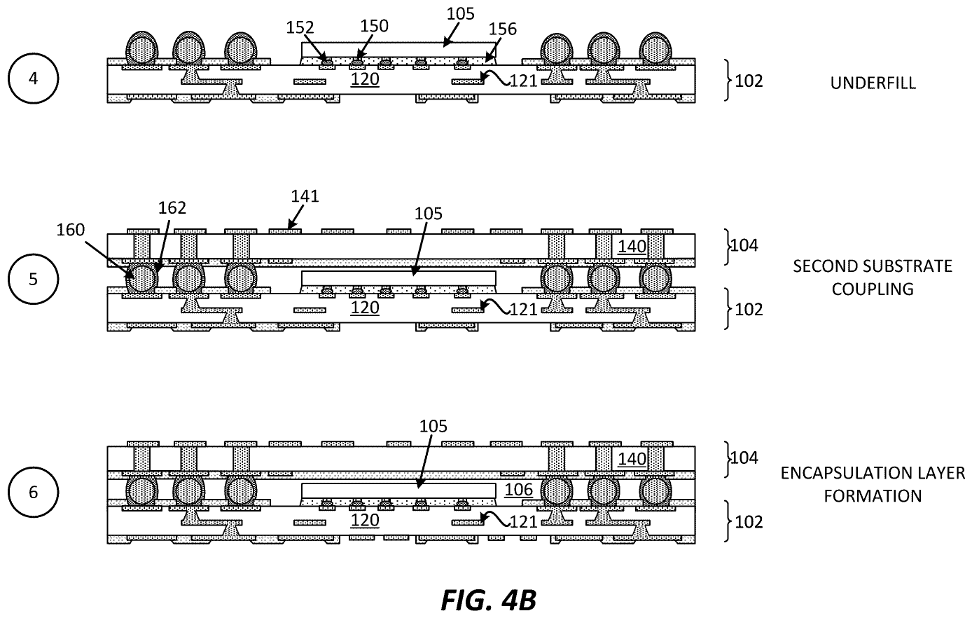

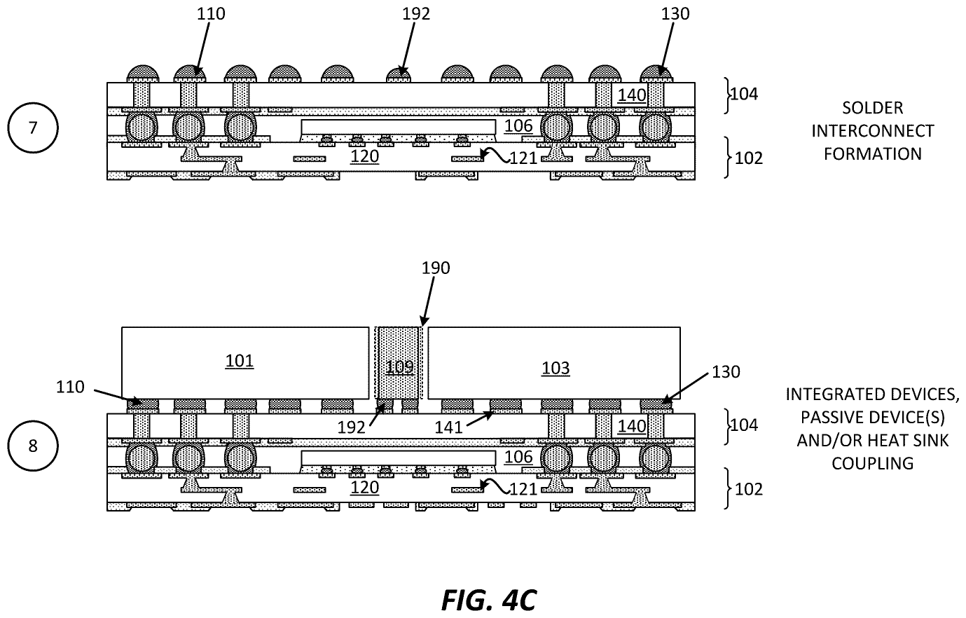

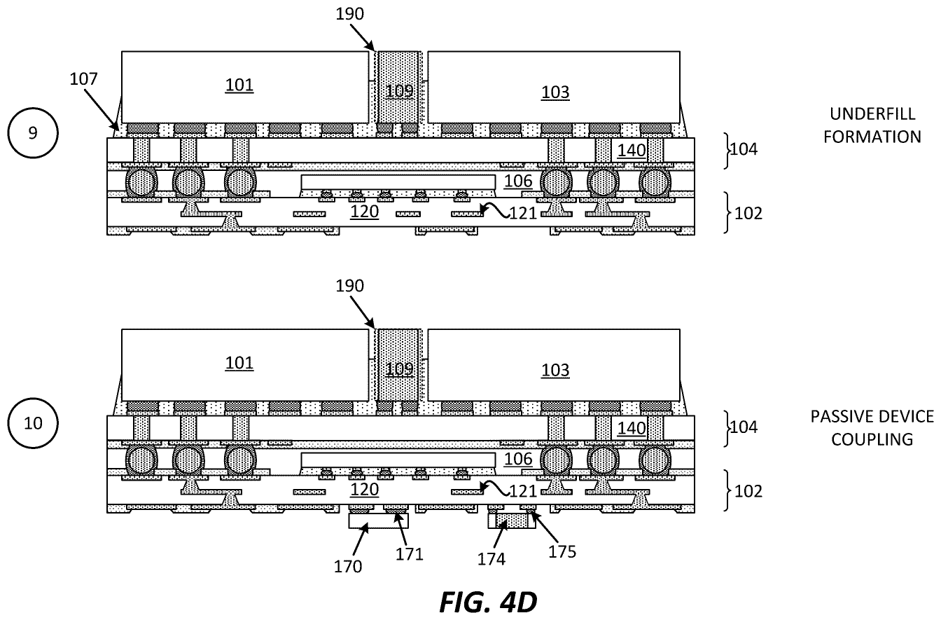

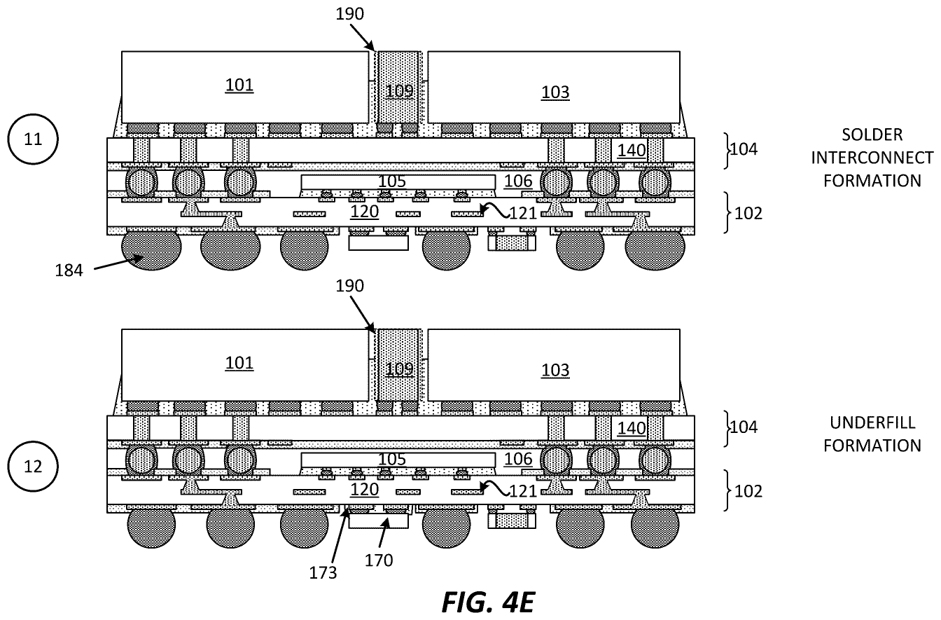

In some implementations, fabricating a package includes several processes. FIGS. 4A-4E illustrate an exemplary sequence for providing or fabricating a package. In some implementations, the sequence of FIGS. 4A-4E may be used to provide or fabricate the package 100. However, the process of FIGS. 4A-4E may be used to fabricate any of the packages (e.g., 600, 700) described in the disclosure.

It should be noted that the sequence of FIGS. 4A-4E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

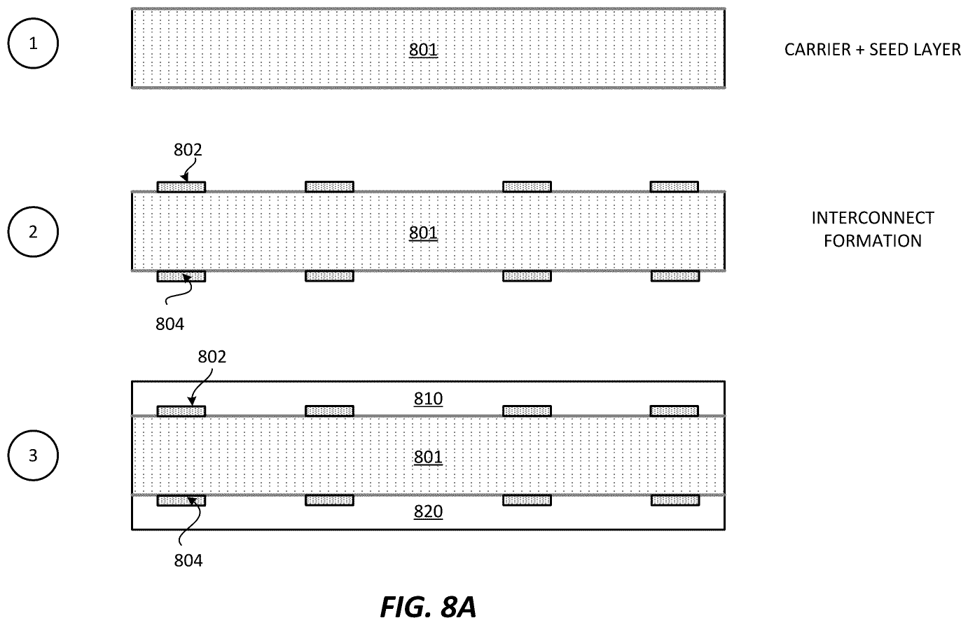

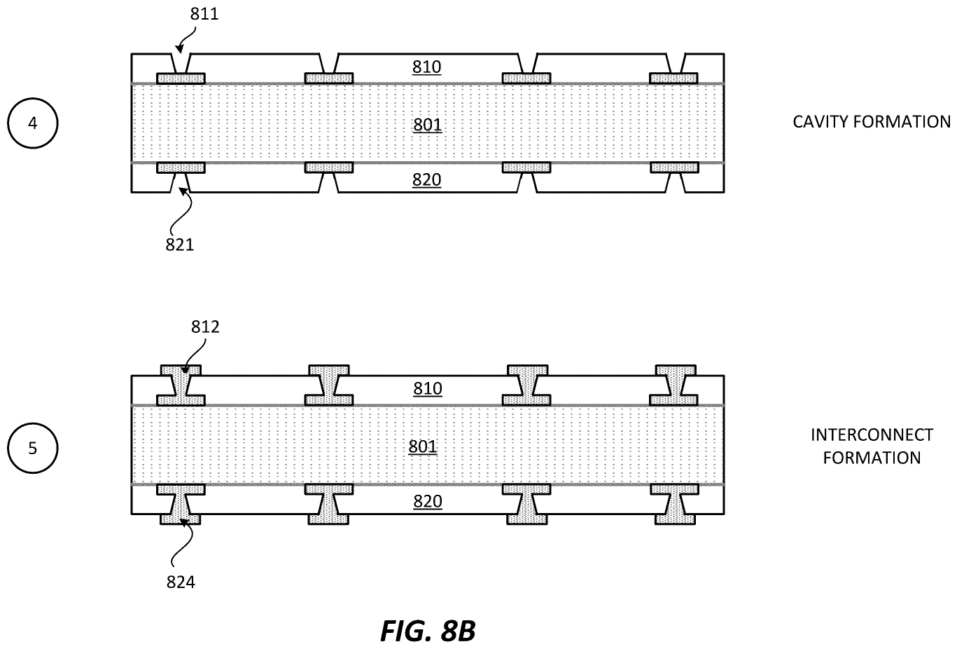

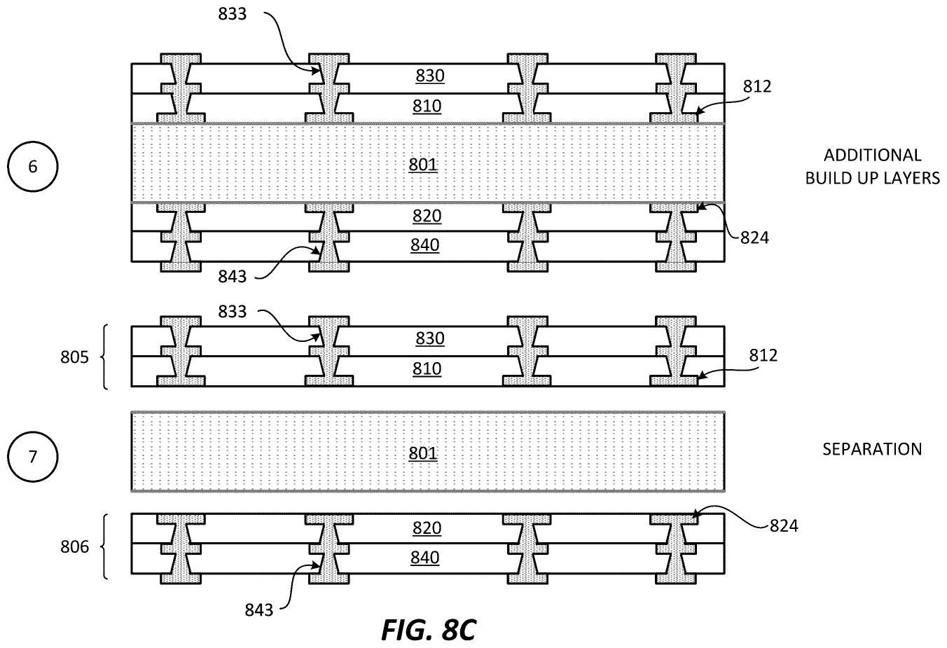

Stage 1, as shown in FIG. 4A, illustrates a state after a substrate 102 is provided. The substrate 102 includes at least one dielectric layer 120, a plurality of interconnects 121, a solder resist layer 124 and a solder resist layer 126. The substrate 102 may be a first substrate. The substrate 102 may include a first surface (e.g., top surface) and a second surface (e.g., bottom surface). The substrate 102 may be fabricated using the method as described in FIGS. 8A-8C.

Stage 2 illustrates a state after an integrated device 105 is coupled to the first surface (e.g., top surface) of the substrate 102. The integrated device 105 is coupled to the substrate 102 through the plurality of pillar interconnects 152 and a plurality of solder interconnects 150. A solder reflow process may be used to couple the integrated device 105 to the substrate 102.

Stage 3 illustrates a state after the plurality of core balls 160 and the plurality of solder interconnects 162 are coupled to the substrate 102. The plurality of core balls 160 and/or the plurality of solder interconnects 162 may be placed and/or dispensed on landing pad interconnects of the plurality of interconnects 121 of the substrate 102. In some implementations, a solder reflow process may be used on the plurality of core balls 160 and/or the plurality of solder interconnects 162 to the substrate 102.

Stage 4, as shown in FIG. 4B, illustrates a state after an underfill 156 is provided and/or formed between the integrated device 105 and the substrate 102. The underfill 156 may be dispensed between the integrated device 105 and the substrate 102. The underfill 156 may at least partially encapsulate the plurality of solder interconnects 150 and the plurality of pillar interconnects 152.

Stage 5 illustrates a state after the substrate 104 is provided and coupled to the substrate 102 through the plurality of core balls 160 and the plurality of solder interconnects 162. The substrate 104 may be a second substrate. The substrate 104 may include an interposer. The substrate 104 includes at least one dielectric layer 140 and a plurality of interconnects 141. A solder reflow process may be used to couple the substrate 104 to the substrate 102. The plurality of core balls 160 and/or the plurality of solder interconnects 162 may be coupled to and touch landing pad interconnects of the plurality of interconnects 141. After the coupling of the substrate 104 to the substrate 102, the integrated device 105 may be located between the substrate 102 and the substrate 104.

Stage 6 illustrates a state after the encapsulation layer 106 is provided between the substrate 102 and the substrate 104. The encapsulation layer 106 may include a mold, a resin, an epoxy and/or a filler. The encapsulation layer 106 may be a means for encapsulation. The encapsulation layer 106 may be provided by using a compression and transfer molding process, a sheet molding process, or a liquid molding process. The encapsulation layer 106 may at least partially encapsulate the integrated device 105, the underfill 156, the plurality of core balls 160 and/or the plurality of solder interconnects 162. The encapsulation layer 106 may include a different material from the underfill 156.

Stage 7, as shown in FIG. 4C, illustrates a state after a plurality of solder interconnects are formed and/or dispensed on the substrate 104. A pasting process may be used to form the plurality of solder interconnects. As shown at stage 7, the plurality of solder interconnects 110, the plurality of solder interconnects 130 and/or the plurality of solder interconnects 192 may be formed and/or dispensed on the landing pad interconnects of the plurality of interconnects 141 of the substrate 104.

Stage 8 illustrates a state after the integrated device 101, the integrated device 103, the heat sink 190 and the passive device 109 are placed and coupled to the substrate 104 through a plurality of solder interconnects. A solder reflow process may be used to couple the integrated device 101, the integrated device 103, the heat sink 190 and the passive device 109 to the substrate 104 through a plurality of solder interconnects. The integrated device 101 may be coupled to the plurality of interconnects 141 through the plurality of solder interconnects 110. The integrated device 103 may be coupled to the plurality of interconnects 141 through the plurality of solder interconnects 130. The passive device 109 may be coupled to the plurality of interconnects 141 through the plurality of solder interconnects 192. The heat sink 190 may be coupled to the plurality of interconnects 141 through at least one solder interconnect.

Stage 9, as shown in FIG. 4D, illustrates a state after an underfill 107 is provided and/or dispensed. The underfill 107 may be located between the integrated device 101 and the substrate 104. The underfill 107 may be located between the integrated device 103 and the substrate 104. The underfill 107 may be located between the passive device 109 and the substrate 104. The underfill 107 may be located between the heat sink 190 and the substrate 104.

Stage 10 illustrates a state after the passive device 170 and the passive device 174 are coupled to a surface of the substrate 102 through a plurality of solder interconnects. A solder reflow process may be used to couple the passive device 170 and the passive device 174 to the substrate 102 through a plurality of solder interconnects. The passive device 170 may be coupled to landing pad interconnects of the plurality of interconnects 121 of the substrate 102 through a plurality of solder interconnects 171. The passive device 174 may be coupled to landing pad interconnects of the plurality of interconnects 121 of the substrate 102 through a plurality of solder interconnects 175.

Stage 11, as shown in FIG. 4E, illustrates a state after a plurality of solder interconnects 184 are coupled to the plurality of interconnects 121 of the substrate 102. A solder reflow process may be used to couple the plurality of solder interconnects 184 to landing pad interconnects of the plurality of interconnects 121.

Stage 12 illustrates a state after an underfill 173 is provided and/or dispensed. The underfill 173 may be located between the passive device 170 and the substrate 102. Stage 12 may illustrate the package 100 of FIG. 1.

### Exemplary Flow Diagram of a Method for Fabricating a Package Comprising a Heat Sink and a Passive Device

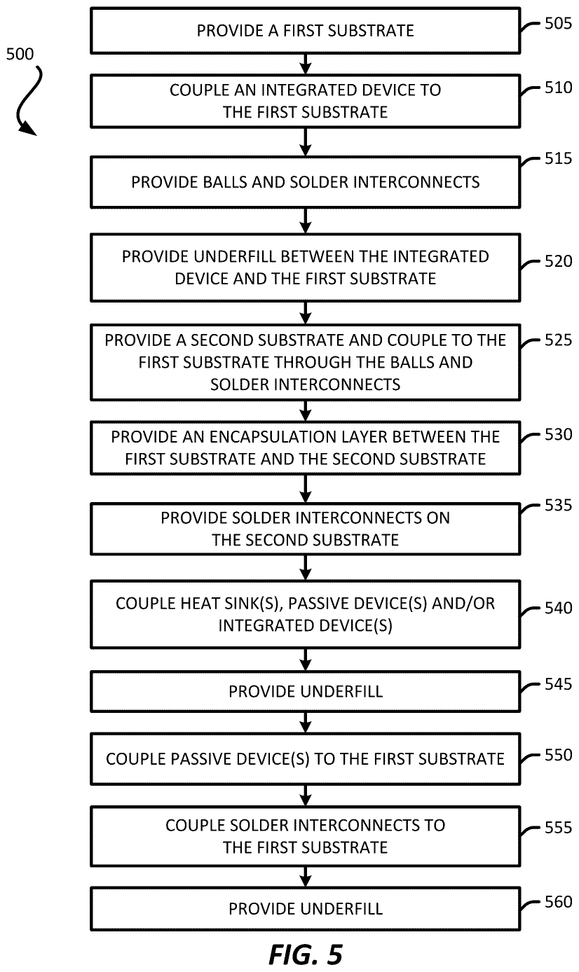

In some implementations, fabricating a package includes several processes. FIG. 5 illustrates an exemplary flow diagram of a method 500 for providing or fabricating a package. In some implementations, the method 500 of FIG. 5 may be used to provide or fabricate the package 100 described in the disclosure. However, the method 500 may be used to provide or fabricate any of the packages (e.g., 600, 700) described in the disclosure.

It should be noted that the method 500 of FIG. 5 may combine one or more processes in order to simplify and/or clarify the method for providing or fabricating a package. In some implementations, the order of the processes may be changed or modified.

The method provides (at 505) a first substrate. Stage 1 of FIG. 4A, illustrates and describes an example of a state after a substrate 102 is provided. The substrate 102 includes at least one dielectric layer 120, a plurality of interconnects 121, a solder resist layer 124 and a solder resist layer 126. The substrate 102 may be a first substrate. The substrate 102 may include a first surface (e.g., top surface) and a second surface (e.g., bottom surface). The substrate 102 may be fabricated using the method as described in FIGS. 8A-8C.

The method couples (at 510) an integrated device to the first substrate. Stage 2 of FIG. 4A, illustrates and describes an example of a state after an integrated device 105 is coupled to the first surface (e.g., top surface) of the substrate 102. The integrated device 105 is coupled to the substrate 102 through the plurality of pillar interconnects 152 and a plurality of solder interconnects 150. A solder reflow process may be used to couple the integrated device 105 to the substrate 102.

The method provides and couples (at 515) a plurality of core balls and a plurality of solder interconnects to the first substrate. Stage 3 of FIG. 4A, illustrates and describes an example of a state after the plurality of core balls 160 and the plurality of solder interconnects 162 are coupled to the substrate 102. The plurality of core balls 160 and/or the plurality of solder interconnects 162 may be placed and/or dispensed on landing pad interconnects of the plurality of interconnects 121 of the substrate 102. In some implementations, a solder reflow process may be used on the plurality of core balls 160 and/or the plurality of solder interconnects 162.

The method provides (at 520) an underfill between the integrated device and the first substrate. Stage 4 of FIG. 4B, illustrates and describes an example of a state after an underfill 156 is provided and/or formed between the integrated device 105 and the substrate 102. The underfill 156 may be dispensed between the integrated device 105 and the substrate 102. The underfill 156 may at least partially encapsulate the plurality of solder interconnects 150 and the plurality of pillar interconnects 152.

The method provides and couples (at 525) a second substrate to the first substrate through the plurality of core balls and/or the plurality of solder interconnects. Stage 5 of FIG. 4B, illustrates and describes an example of a state after the substrate 104 is provided and coupled to the substrate 102 through the plurality of core balls 160 and the plurality of solder interconnects 162. The substrate 104 may be a second substrate. The substrate 104 may include an interposer. The substrate 104 includes at least one dielectric layer 140 and a plurality of interconnects 141. A solder reflow process may be used to couple the substrate 104 to the substrate 102. The plurality of core balls 160 and/or the plurality of solder interconnects 162 may be coupled to and touch landing pad interconnects of the plurality of interconnects 141. After the coupling of the substrate 104 to the substrate 102, the integrated device 105 may be located between the substrate 102 and the substrate 104.

The method provides (at 530) an encapsulation layer between the first substrate and the second substrate. Stage 6 of FIG. 4B, illustrates and describes an example of a state after the encapsulation layer 106 is provided between the substrate 102 and the substrate 104. The encapsulation layer 106 may include a mold, a resin, an epoxy and/or a filler. The encapsulation layer 106 may be a means for encapsulation. The encapsulation layer 106 may be provided by using a compression and transfer molding process, a sheet molding process, or a liquid molding process. The encapsulation layer 106 may at least partially encapsulate the integrated device 105, the underfill 156, the plurality of core balls 160 and/or the plurality of solder interconnects 162.

The method provides and couples (at 535) a plurality of solder interconnects to the second substrate. Stage 7 of FIG. 4C, illustrates and describes an example of a state after a plurality of solder interconnects are formed and/or dispensed on the substrate 104. A pasting process may be used to form the plurality of solder interconnects. As shown at stage 7, the plurality of solder interconnects 110, the plurality of solder interconnects 130 and/or the plurality of solder interconnects 192 may be formed and/or dispensed on the landing pad interconnects of the plurality of interconnects 141 of the substrate 104.

The method couples (at 540) integrated devices, at least one heat sink and/or at least one passive device to the second substrate. Stage 8 of FIG. 4C, illustrates and describes an example of a state after the integrated device 101, the integrated device 103, the heat sink 190 and the passive device 109 are placed and coupled to the substrate 104 through a plurality of solder interconnects. A solder reflow process may be used to couple the integrated device 101, the integrated device 103, the heat sink 190 and the passive device 109 to the substrate 104 through a plurality of solder interconnects. The integrated device 101 may be coupled to the plurality of interconnects 141 through the plurality of solder interconnects 110. The integrated device 103 may be coupled to the plurality of interconnects 141 through the plurality of solder interconnects 130. The passive device 109 may be coupled to the plurality of interconnects 141 through the plurality of solder interconnects 192. The heat sink 190 may be coupled to the plurality of interconnects 141 through at least one solder interconnect.

The method provides (at 545) an underfill between the integrated devices and the second substrate. Stage 9 of FIG. 4D, illustrates and describes an example of a state after an underfill 107 is provided and/or dispensed. The underfill 107 may be located between the integrated device 101 and the substrate 104. The underfill 107 may be located between the integrated device 103 and the substrate 104. The underfill 107 may be located between the passive device 109 and the substrate 104. The underfill 107 may be located between the heat sink 190 and the substrate 104.

The method couples (at 550) at least one passive device to the first substrate. Stage 10 of FIG. 4D, illustrates and describes an example of a state after the passive device 170 and the passive device 174 are coupled to a surface of the substrate 102 through a plurality of solder interconnects. A solder reflow process may be used to couple the passive device 170 and the passive device 174 to the substrate 102 through a plurality of solder interconnects. The passive device 170 is coupled to landing pad interconnects of the plurality of interconnects 121 of the substrate 102 through a plurality of solder interconnects 171. The passive device 174 is coupled to landing pad interconnects of the plurality of interconnects 121 of the substrate 102 through a plurality of solder interconnects 175.

The method couples (at 555) a plurality of solder interconnects to the first substrate. Stage 11 of FIG. 4E, illustrates and describes an example of a state after a plurality of solder interconnects 184 are coupled to the plurality of interconnects 121 of the substrate 102. A solder reflow process may be used to couple the plurality of solder interconnects 184 to landing pad interconnects of the plurality of interconnects 121.

The method provides (at 560) an underfill between the first substrate and the passive device. Stage 12 of FIG. 4E, illustrates and describes an example of a state after an underfill 173 is provided and/or dispensed. The underfill 173 may be located between the passive device 170 and the substrate 102. Stage 12 of FIG. 4E may illustrate the package 100 of FIG. 1.

### Exemplary Packages Comprising a Heat Sink and/or a Passive Device

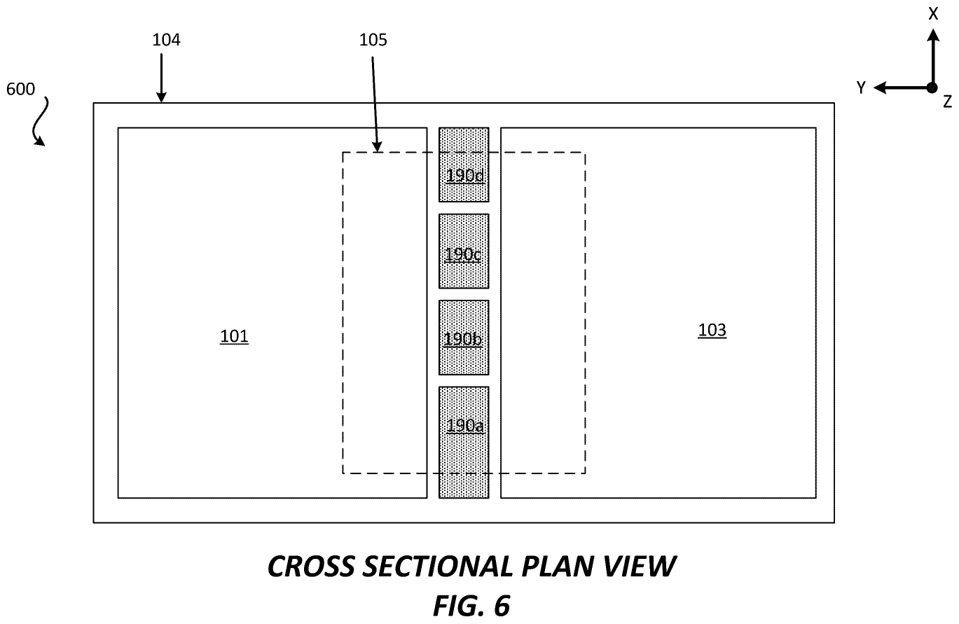

FIG. 6 illustrates a cross sectional plan view of a package 600 that may include integrated devices and at least one heat sink. The package 600 is similar to the package 100 of FIG. 1 and may include similar components as described for the package 100. The package 600 may include the substrate 104, the integrated device 105, the integrated device 101, the integrated device 103, the heat sink 190a, the heat sink 190b, the heat sink 190c and the heat sink 190d. The heat sink 190a, the heat sink 190b, the heat sink 190c and the heat sink 190d are located laterally between the integrated device 101 and the integrated device 103. The heat sink 190a, the heat sink 190b, the heat sink 190c and the heat sink 190d are arranged in a row between the integrated device 101 and the integrated device 103. The passive device 109, the heat sink 190a, the heat sink 190b, the heat sink 190c and/or the heat sink 190d vertically overlap with at least a portion of the integrated device 105. The heat sink 190a, the heat sink 190b, the heat sink 190c and the heat sink 190d are coupled to the substrate 104 through a plurality of solder interconnects. The heat sink 190a, the heat sink 190b, the heat sink 190c and/or the heat sink 190d may have similar lengths and/or different lengths. In some implementations, the heat sink 190a, the heat sink 190b, the heat sink 190c and the heat sink 190d may each have a length that is less than 50 percent of (i) the length and/or the width of the integrated device 101 and/or (ii) the length and/or the width of the integrated device 103.

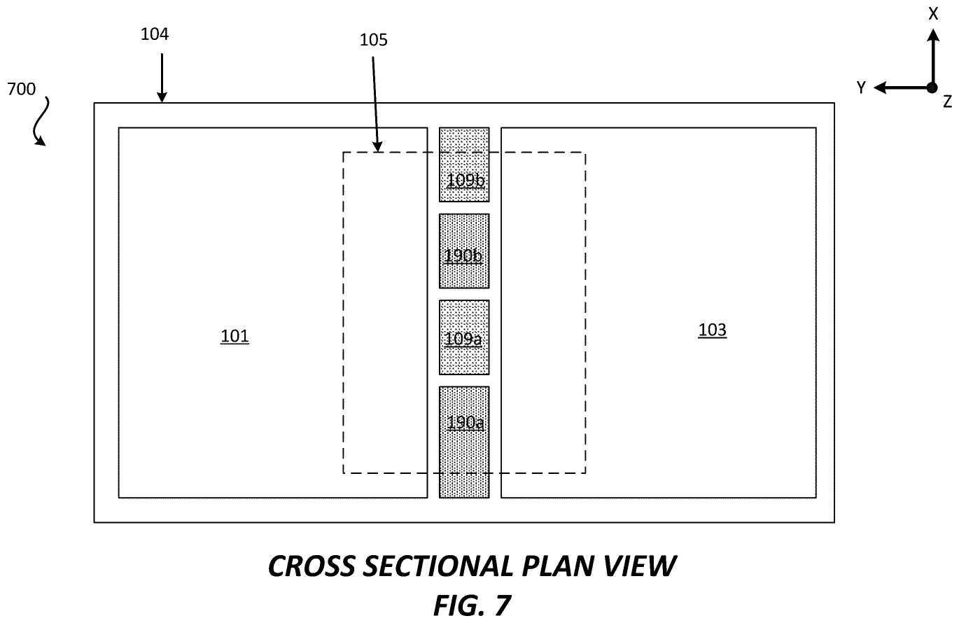

FIG. 7 illustrates a cross sectional plan view of a package 700 that may include integrated devices and at least one heat sink. The package 700 is similar to the package 100 of FIG. 1 and may include similar components as described for the package 100. The package 700 may include the substrate 104, the integrated device 105, the integrated device 101, the integrated device 103, the passive device 109a, the passive device 109b, the heat sink 190a and the heat sink 190b. The passive device 109a, the passive device 109b, the heat sink 190a and the heat sink 190b are located laterally between the integrated device 101 and the integrated device 103. The passive device 109a, the passive device 109b, the heat sink 190a and the heat sink 190b are arranged in a row between the integrated device 101 and the integrated device 103. The passive device 109a, the passive device 109b, the heat sink 190a and the heat sink 190b vertically overlap with at least a portion of the integrated device 105. The passive device 109a, the passive device 109b, the heat sink 190a and the heat sink 190b are coupled to the substrate 104 through a plurality of solder interconnects. In some implementations, the passive device 109a and the passive device 109b may include the same type of passive device. In some implementations, the passive device 109a and the passive device 109b may include different types of passive devices. The heat sink 190a, the heat sink 190b, the passive device 109a and/or the passive device 109b may have similar lengths and/or different lengths. In some implementations, the heat sink 190a, the heat sink 190b, the passive device 109 a and/or the passive device 109 b may each have a length that is less than 50 percent of (i) the length and/or the width of the integrated device 101 and/or (ii) the length and/or the width of the integrated device 103.

Different implementations may have different numbers of the heat sink (e.g., 190a) and/or different numbers of the passive device 109. Different implementations may have different configurations and/or arrangements of the heat sink and/or the passive device. Different implementations may have one or more heat sinks with different sizes and/or shapes. Different implementations may have one or more passive devices with different sizes and/or shapes. Different implementations may have one or more passive devices with different passive device types. In some implementations, using smaller heat sinks instead of one big heat sink provides a more reliable coupling between the heat sink and the substrate 104, which helps provide more effective and efficient heat dissipation away from the integrated device 105.

### Exemplary Sequence for Fabricating a Substrate

In some implementations, fabricating a substrate includes several processes. FIGS. 8A-8C illustrate an exemplary sequence for providing or fabricating a substrate. In some implementations, the sequence of FIGS. 8A-8C may be used to provide or fabricate a laminated substrate. The substrate that is fabricated in FIGS. 8A-8C may replace the substrate 102 of the disclosure.

It should be noted that the sequence of FIGS. 8A-8C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 8A, illustrates a state after a carrier 801 is provided. The carrier 801 may include a core layer. The core layer may include seed layers on surfaces of the core layer.

Stage 2 illustrates a state after a plurality of interconnects 802 and a plurality of interconnects 804 are formed. The plurality of interconnects 802 may be coupled to a first surface (e.g., top surface) of the carrier 801. The plurality of interconnects 804 may be coupled to a second surface (e.g., bottom surface) of the carrier 801. A plating process may be used to form the plurality of interconnects 802 and the plurality of interconnects 804. The plurality of interconnects 802 may be formed on a first seed layer of the carrier 801. The plurality of interconnects 804 may be formed on a second seed layer of the carrier 801.

Stage 3 illustrates a state after a dielectric layer 810 and a dielectric layer 820 are provided. The dielectric layer 810 may be coupled to the first surface of the carrier 801. The dielectric layer 820 may be coupled to the second surface of the carrier 801. A deposition and/or a lamination process may be used to form the dielectric layer 810 and/or the dielectric layer 820. The dielectric layer 810 and/or the dielectric layer 820 may include prepreg, polymer and/or Ajinomoto Build-up Film (ABF).

Stage 4 of FIG. 8B, illustrates a state after a plurality of cavities 811 are formed in the dielectric layer 810, and a plurality of cavities 821 are formed in the dielectric layer 820. An exposure and development process may be used to form the plurality of cavities 811 in the dielectric layer 810 and the plurality of cavities 821 in the dielectric layer 820. Different implementations may use different processes to form the plurality of cavities. The plurality of cavities 811 and/or the plurality of cavities 821 may be openings in dielectric layer(s).

Stage 5 illustrates a state after a plurality of interconnects 812 are formed in the dielectric layer 810, and a plurality of interconnects 824 are formed in the dielectric layer 820. The plurality of interconnects 812 may be coupled to the plurality of interconnects 802. The plurality of interconnects 824 may be coupled to the plurality of interconnects 804. A plating process may be used to form the plurality of interconnects 812 and/or the plurality of interconnects 824.

Stage 6, as shown in FIG. 8C, illustrates a state after additional build up layers are formed. For example, stage 6 illustrates a state after additional dielectric layers and additional interconnects are formed. For example, a dielectric layer 830 may be formed and coupled to the dielectric layer 810. A dielectric layer 840 may be formed and coupled to the dielectric layer 820. A lamination process and/or a deposition process may be used to form the dielectric layer 830 and the dielectric layer 840.

Stage 6 further illustrates a state after a plurality of interconnects 833 are formed in and over the dielectric layer 830, and after a plurality of interconnects 843 are formed in and over the dielectric layer 840. The plurality of interconnects 833 may be coupled to the plurality of interconnects 812. The plurality of interconnects 843 may be coupled to the plurality of interconnects 824. A plurality of cavities may be formed in the dielectric layer 830 and the dielectric layer 840 in a similar manner as described for forming a plurality of cavities in Stage 4 of FIG. 8B. The plurality of interconnects 833 and the plurality of interconnects 843 may be formed in a similar manner as described for fabricating a plurality of interconnects in Stage 5 of FIG. 8B.

Stage 7 illustrates a state after separation of the dielectric layers from the carrier 801. For example, the dielectric layer 810, the dielectric layer 830, the plurality of interconnects 802, the plurality of interconnects 812 and the plurality of interconnects 833 are separated from the carrier 801 to form a substrate 805 (e.g., coreless substrate). In another example, the dielectric layer 820, the dielectric layer 840, the plurality of interconnects 804, the plurality of interconnects 824 and the plurality of interconnects 843 are separated from the carrier 801 to form a substrate 806 (e.g., coreless substrate).

The substrate 805 and/or the substrate 806 may be used instead of the substrate 102, in the package 100 and/or the package 200. In some implementations, once separation occurs, one or more solder resist layers may be formed on surface(s) of the substrate 805 and/or the substrate 806.

### Exemplary Flow Diagram of a Method for Fabricating a Substrate

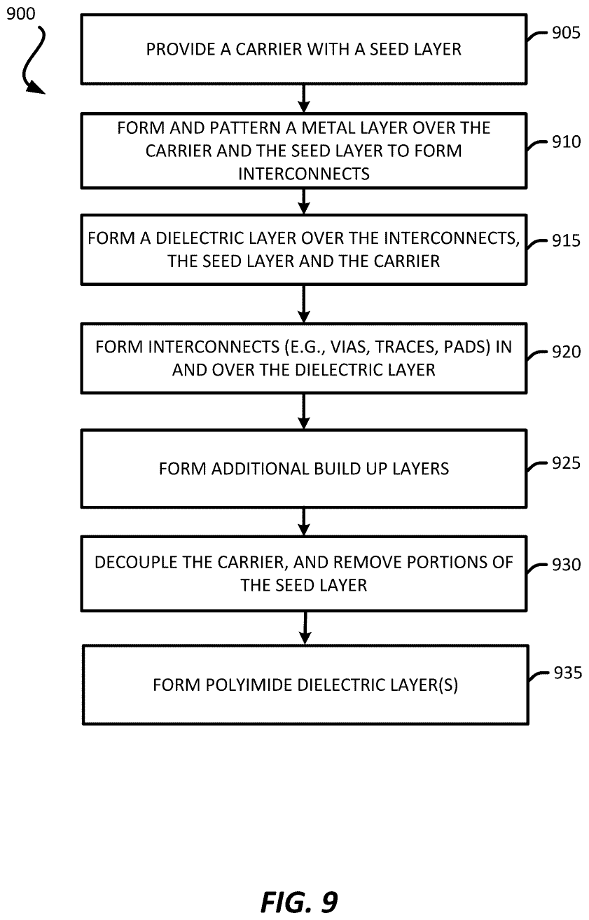

In some implementations, fabricating a substrate includes several processes. FIG. 9 illustrates an exemplary flow diagram of a method 900 for providing or fabricating a substrate. In some implementations, the method 900 of FIG. 9 may be used to provide or fabricate a substrate.

It should be noted that the method 900 of FIG. 9 may combine one or more processes in order to simplify and/or clarify the method for providing or fabricating a substrate. In some implementations, the order of the processes may be changed or modified.

The method provides (at 905) a carrier. The carrier may include seed layers. Stage 1 of FIG. 8A, illustrates and describes an example of a state after a carrier 801 is provided. The carrier 801 may include a core layer. The core layer may include seed layers on surfaces of the core layer.

The method forms (at 910) a plurality of interconnects on the carrier and/or the seed layer(s). Stage 2 of FIG. 8A, illustrates and describes an example of a state after a plurality of interconnects 802 and a plurality of interconnects 804 are formed. The plurality of interconnects 802 may be coupled to a first surface (e.g., top surface) of the carrier 801. The plurality of interconnects 804 may be coupled to a second surface (e.g., bottom surface) of the carrier 801. A plating process may be used to form the plurality of interconnects 802 and the plurality of interconnects 804. The plurality of interconnects 802 may be formed on a first seed layer of the carrier 801. The plurality of interconnects 804 may be formed on a second seed layer of the carrier 801.

The method forms (at 915) at least one dielectric layer over the plurality of interconnects, the seed layer(s) and/or the carrier. Stage 3 of FIG. 8A, illustrates and describes an example of a state after a dielectric layer 810 and a dielectric layer 820 are provided. The dielectric layer 810 may be coupled to the first surface of the carrier 801. The dielectric layer 820 may be coupled to the second surface of the carrier 801. A deposition and/or a lamination process may be used to form the dielectric layer 810 and/or the dielectric layer 820. The dielectric layer 810 and/or the dielectric layer 820 may include prepreg, polymer and/or Ajinomoto Build-up Film (ABF).

The method forms (at 920) interconnects in and over the dielectric layer. For example, via interconnects, trace interconnects and/or pad interconnects may be formed as the interconnects. Forming the plurality of interconnects may include forming a plurality of cavities in the dielectric layer(s). Stage 4 of FIG. 8B, illustrates and describes an example of a state after a plurality of cavities 811 are formed in the dielectric layer 810, and a plurality of cavities 821 are formed in the dielectric layer 820. An exposure and development process may be used to form the plurality of cavities 811 in the dielectric layer 810 and the plurality of cavities 821 in the dielectric layer 820. Different implementations may use different processes to form the plurality of cavities.

Stage 5 of FIG. 8B, illustrates and describes an example of a state after a plurality of interconnects 812 are formed in the dielectric layer 810, and a plurality of interconnects 824 are formed in the dielectric layer 820. The plurality of interconnects 812 may be coupled to the plurality of interconnects 802. The plurality of interconnects 824 may be coupled to the plurality of interconnects 804. A plating process may be used to form the plurality of interconnects 812 and/or the plurality of interconnects 824.

The method forms (at 925) additional build up layers. Stage 6 of FIG. 8C, illustrates and describes an example of a state after additional build up layers are formed. For example, stage 6 illustrates a state after additional dielectric layers and additional interconnects are formed. For example, a dielectric layer 830 may be formed and coupled to the dielectric layer 810. A dielectric layer 840 may be formed and coupled to the dielectric layer 820. A lamination process and/or a deposition process may be used to form the dielectric layer 830 and the dielectric layer 840.

Stage 6 of FIG. 8C, further illustrates and describes an example of a state after a plurality of interconnects 833 are formed in and over the dielectric layer 830, and after a plurality of interconnects 843 are formed in and over the dielectric layer 840. The plurality of interconnects 833 may be coupled to the plurality of interconnects 812. The plurality of interconnects 843 may be coupled to the plurality of interconnects 824. A plurality of cavities may be formed in the dielectric layer 830 and the dielectric layer 840 in a similar manner as described for forming a plurality of cavities in Stage 4 of FIG. 8B. The plurality of interconnects 833 and the plurality of interconnects 843 may be formed in a similar manner as described for fabricating a plurality of interconnects in Stage 5 of FIG. 8B.

The method decouples (at 930) the carrier from the dielectric layers. The method may further remove portions of the seed layer(s). Stage 7 of FIG. 8C, illustrates and describes an example of a state after separation of the dielectric layers from the carrier 801. For example, the dielectric layer 810, the dielectric layer 830, the plurality of interconnects 802, the plurality of interconnects 812 and the plurality of interconnects 833 are separated from the carrier 801 to form a substrate 805 (e.g., coreless substrate). In another example, the dielectric layer 820, the dielectric layer 840, the plurality of interconnects 804, the plurality of interconnects 824 and the plurality of interconnects 843 are separated from the carrier 801 to form a substrate 806 (e.g., coreless substrate). The substrate 805 and/or the substrate 806 may be used instead of the substrate 102, in the package 100 and/or the package 200.

The method may further form (at 935) solder resist layer(s) on the substrate. In some implementations, once separation occurs, one or more solder resist layers may be formed on surface(s) of the substrate 805 and/or the substrate 806.

### Exemplary Electronic Devices

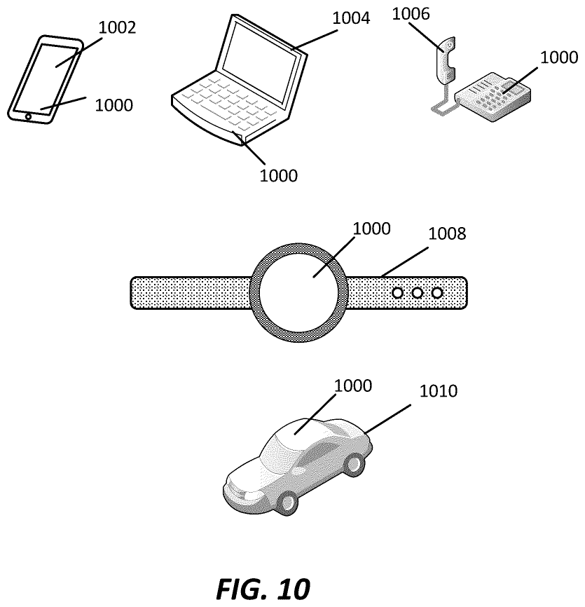

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4E, 5-7, 8A-8C and 9-10 may be rearranged and/or combined into a single component, process, feature or function or embodied in several components, processes, or functions. Additional elements, components, processes, and/or functions may also be added without departing from the disclosure. It should also be noted FIGS. 1-3, 4A-4E, 5-7, 8A-8C and 9-10 and its corresponding description in the present disclosure is not limited to dies and/or ICs. In some implementations, FIGS. 1-3, 4A-4E, 5-7, 8A-8C and 9-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; at least one passive device located between the second integrated device and the third integrated device; and at least one heat sink located between the second integrated device and the third integrated device.

Aspect 2: The package of aspect 1, wherein the at least one passive device is coupled to a power distribution network of the package.

Aspect 3: The package of aspects 1 through 2, wherein the at least one passive device and the at least one heat sink are arranged in a row between the second integrated device and the third integrated device.

Aspect 4: The package of aspects 1 through 3, wherein the at least one passive device includes a deep trench capacitor device.

Aspect 5: The package of aspects 1 through 4, further comprising an underfill coupled to the second substrate.

Aspect 6: The package of aspect 5, wherein the underfill is located (i) between the second substrate and the at least one passive device, and (ii) between the second substrate and the at least one heat sink.

Aspect 7: The package of aspects 1 through 6, wherein the second substrate is coupled to the first substrate through a plurality of core balls and the plurality of solder interconnects.

Aspect 8: The package of aspects 1 through 7, wherein the second integrated device includes a first package comprising a first die, and wherein the third integrated device includes a second package comprising a second die.

Aspect 9: The package of aspects 1 through 8, wherein the at least one passive device is coupled to the second substrate.

Aspect 10: The package of aspects 1 through 9, wherein the second substrate includes an interposer.

Aspect 11: A package comprising a first substrate; a first integrated device coupled to the first substrate; a second substrate coupled to the first substrate through at least a plurality of solder interconnects; an encapsulation layer located between the first substrate and the second substrate; a second integrated device coupled to the second substrate; a third integrated device coupled to the second substrate; and at least two heat sinks located between the second integrated device and the third integrated device.

Aspect 12: The package of aspect 11, wherein the at least two heat sinks are arranged in a row between the second integrated device and the third integrated device.

Aspect 13: The package of aspects 11 through 12, further comprising an underfill coupled to the second substrate, wherein the underfill is located between the second substrate and the at least two heat sinks.

Aspect 14: The package of aspects 11 through 13, further comprising a passive integrated device located between the second integrated device and the third integrated device.

Aspect 15: The package of aspects 11 through 14, wherein the second substrate is coupled to the first substrate through a plurality of core balls and the plurality of solder interconnects.

Aspect 16: The package of aspects 11 through 15, wherein the second integrated device includes a first package comprising a first die, and wherein the third integrated device includes a second package comprising a second die.

Aspect 17: A method for fabricating a package. The method provides a first substrate. The method couples a first integrated device to the first substrate. The method couples a second substrate to the first substrate through at least a plurality of solder interconnects. The method provides an encapsulation layer located between the first substrate and the second substrate. The method couples a second integrated device to the second substrate through a second plurality of solder interconnects. The method couples a third integrated device to the second substrate through a third plurality of solder interconnects. The method provides at least two heat sinks located between the second integrated device and the third integrated device.

Aspect 18: The method of aspect 17, wherein the at least two heat sinks are arranged in a row between the second integrated device and the third integrated device.

Aspect 19: The method of aspects 17 through 18, further comprising providing at least one passive device located between the second integrated device and the third integrated device.

Aspect 20: The method of aspect 19, wherein the at least one passive device includes a deep trench capacitor device.

Aspect 21: A device comprising aspects 1 through 16, wherein the device is from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
a first integrated device coupled to the first substrate;
a second substrate coupled to the first substrate through at least a plurality of solder interconnects;
an encapsulation layer located between the first substrate and the second substrate;
a second integrated device coupled to the second substrate;
a third integrated device coupled to the second substrate;
at least one passive device located between the second integrated device and the third integrated device; and
at least one heat sink located between the second integrated device and the third integrated device.

2. The package of claim 1, wherein the at least one passive device is coupled to a power distribution network of the package.

3. The package of claim 1, wherein the at least one passive device and the at least one heat sink are arranged in a row between the second integrated device and the third integrated device.

4. The package of claim 1, wherein the at least one passive device includes a deep trench capacitor device.

5. The package of claim 1, further comprising an underfill coupled to the second substrate.

6. The package of claim 5, wherein the underfill is located (i) between the second substrate and the at least one passive device, and (ii) between the second substrate and the at least one heat sink.

7. The package of claim 1, wherein the second substrate is coupled to the first substrate through a plurality of core balls and the plurality of solder interconnects.

8. The package of claim 1,
wherein the second integrated device includes a first package comprising a first die, and
wherein the third integrated device includes a second package comprising a second die.

9. The package of claim 1, wherein the at least one passive device is coupled to the second substrate.

10. The package of claim 1, wherein the second substrate includes an interposer.

11. A package comprising:
a first substrate;
a first integrated device coupled to the first substrate;
a second substrate coupled to the first substrate through at least a plurality of solder interconnects;
an encapsulation layer located between the first substrate and the second substrate;
a second integrated device coupled to the second substrate;
a third integrated device coupled to the second substrate; and
at least two heat sinks located between the second integrated device and the third integrated device.

12. The package of claim 11, wherein the at least two heat sinks are arranged in a row between the second integrated device and the third integrated device.

13. The package of claim 11, further comprising an underfill coupled to the second substrate, wherein the underfill is located between the second substrate and the at least two heat sinks.

14. The package of claim 11, further comprising a passive integrated device located between the second integrated device and the third integrated device.

15. The package of claim 11, wherein the second substrate is coupled to the first substrate through a plurality of core balls and the plurality of solder interconnects.

16. The package of claim 11,
wherein the second integrated device includes a first package comprising a first die, and
wherein the third integrated device includes a second package comprising a second die.

17. A method for fabricating a package, comprising:
providing a first substrate;
coupling a first integrated device to the first substrate;
coupling a second substrate to the first substrate through at least a plurality of solder interconnects;
providing an encapsulation layer located between the first substrate and the second substrate;
coupling a second integrated device to the second substrate through a second plurality of solder interconnects;
coupling a third integrated device to the second substrate through a third plurality of solder interconnects; and
providing at least two heat sinks located between the second integrated device and the third integrated device.

18. The method of claim 17, wherein the at least two heat sinks are arranged in a row between the second integrated device and the third integrated device.

19. The method of claim 17, further comprising providing at least one passive device located between the second integrated device and the third integrated device.

20. The method of claim 19, wherein the at least one passive device includes a deep trench capacitor device.
